(19) United States
(12) Patent Application Publication
(10) Pub. No.: US 2025/0275331 A1
(43) Pub. Date: Aug. 28, 2025

(54) SEMICONDUCTOR DEVICE, METHOD OF MANUFACTURING THE SEMICONDUCTOR DEVICE, AND ELECTRONIC DEVICE INCLUDING THE SEMICONDUCTOR DEVICE

(71) Applicant: Samsung Display Co., LTD., Yongin-si (KR)

(72) Inventor: JUNGHWAN HWANG, Yongin-si (KR)

(21) Appl. No.: 19/030,588

(22) Filed: Jan. 17, 2025

(30) Foreign Application Priority Data
Feb. 27, 2024 (KR) 10-2024-0027832

(51) Int. Cl. H10H 29/32; H10H 29/01

(52) U.S. Cl. CPC H10H 29/32; H10H 29/012

(57) ABSTRACT

A semiconductor device includes a first impurity region, a second impurity region spaced from the first impurity region by a first length in a first direction, and a first channel region having a third length longer than the first length between the first and second impurity regions, a convex portion in a second direction between the first and second impurity regions, a third impurity region, a fourth impurity region spaced from the third impurity region by a second length in the first direction, and a second channel region having a fourth length longer than the second length between the third and fourth impurity regions, a concave portion opposite to the second direction between the third and fourth impurity regions, a first gate electrode above the first channel region and covering the convex portion, and a second gate electrode above the second channel region and filling the concave portion.

### CROSS-REFERENCE TO RELATED APPLICATION

The present application claims priority to, and the benefit of, Korean Patent Application No. 10-2024-0027832, filed on Feb. 27, 2024, in the Korean Intellectual Property Office, the entire disclosure of which is incorporated herein by reference.

### BACKGROUND

### 1. Field

The present disclosure relates to a semiconductor device that provides visual information, method of manufacturing the semiconductor device, and an electronic device including the semiconductor device.

### 2. Description of the Related Art

As semiconductor devices become more sophisticated, dimensions of semiconductor devices formed on semiconductor substrates are becoming increasingly finer. When the semiconductor device has fine dimensions, an area occupied by a gate structure of a transistor must also be reduced, so various methods have been studied to increase a length of a gate channel even within the reduced area. As one of the methods for increasing a length of the gate channel, a trench gate structure has been studied.

### SUMMARY

The present disclosure provides a semiconductor device with improved reliability, and a method of manufacturing the semiconductor device.

A semiconductor device according to one or more embodiments of the present disclosure includes a substrate including a first region including a first impurity region, a second impurity region spaced apart from the first impurity region by a first length in a first direction in plan view, and a first channel region having a third length that is longer than the first length between the first impurity region and the second impurity region, the first region defining a convex portion that is convex in a second direction crossing the first direction between the first impurity region and the second impurity region, a second region including a third impurity region, a fourth impurity region spaced apart from the third impurity region by a second length in the first direction in plan view, and a second channel region having a fourth length that is longer than the second length between the third impurity region and the fourth impurity region, the second region defining a concave portion that is concave in a direction opposite to the second direction between the third impurity region and the fourth impurity region, a first gate electrode above the first channel region, and covering the convex portion, and a second gate electrode above the second channel region, and filling the concave portion.

The semiconductor device may further include a device isolation layer between the first region and the second region.

The third length and the fourth length may be about 3 μm or more.

The concave portion may be U-shaped or V-shaped in a cross-sectional view.

The first impurity region and the second impurity region may be doped with a P-type material, wherein the third impurity region and the fourth impurity region are doped with an N-type material.

The first, second, third, and fourth impurity regions may be doped with a P-type material.

The first, second, third, and fourth impurity regions may be doped with an N-type material.

The semiconductor device may further include a first insulating layer between the substrate and the first gate electrode in the first region, and a second insulating layer between the substrate and the second gate electrode in the second region.

The first insulating layer may overlap the first gate electrode in plan view, wherein the second insulating layer overlaps the second gate electrode in plan view.

The first channel region may be at a lower portion of the first insulating layer, wherein the second channel region is at a lower portion of the second insulating layer.

A level of an upper surface of the convex portion may be substantially equal to a level of an upper surface of the third impurity region.

The semiconductor device may further include first low-concentration impurity regions between the first impurity region and the first channel region, and between the second impurity region and the first channel region, and second low-concentration impurity regions between the third impurity region and the second channel region, and between the fourth impurity region and the second channel region.

The first low-concentration impurity regions may be doped with a same material as the first impurity region, wherein the second low-concentration impurity regions are doped with a same material as the third impurity region.

The semiconductor device may further include a silicide above the first, second, third, and fourth impurity regions, the first gate electrode, and the second gate electrode.

A method of manufacturing a semiconductor device according to one or more embodiments of the present disclosure includes providing a substrate including a first region, and a second region adjacent to the first region in a first direction, forming a device isolation layer between the first region and the second region, forming a convex portion that is convex in a second direction crossing the first direction in a central portion of the first region and a concave portion that is concave in a direction opposite to the second direction in a central portion of the second region by etching the substrate, forming a first gate electrode that covers the convex portion of the first region, and forming a second gate electrode that fills the concave portion of the second region.

The method may further include, after forming the concave portion and the convex portion, forming a first insulating layer between the substrate and the first gate electrode in the first region, and a second insulating layer between the substrate and the second gate electrode in the second region.

A length of a first channel region beneath the first insulating layer, and a length of a second channel region beneath the second insulating layer, may be about 3 μm or more.

The method may further include, after providing the substrate, doping at least a portion of the first region with an impurity.

The impurity may be an N-type material.

The substrate may be doped with a P-type material.

An electronic device according to one or more embodiments of the present disclosure includes a display device and a processor that drives the display device, and wherein the display device includes a substrate comprising a first region comprising, a first impurity region, a second impurity region spaced apart from the first impurity region by a first length in a first direction in a plan view, and a first channel region having a third length that is longer than the first length between the first impurity region and the second impurity region, the first region defining a convex portion that is convex in a second direction crossing the first direction between the first impurity region and the second impurity region, a second region comprising, a third impurity region, a fourth impurity region spaced apart from the third impurity region by a second length in the first direction in a plan view, and a second channel region having a fourth length that is longer than the second length between the third impurity region and the fourth impurity region, the second region defining a concave portion that is concave in a direction opposite to the second direction between the third impurity region and the fourth impurity region, a first gate electrode above the first channel region, and covering the convex portion, and a second gate electrode above the second channel region, and filling the concave portion.

A display device according to embodiments of the present disclosure may include a substrate including a first region including a first impurity region, a second impurity region spaced apart from the first impurity region by a first length in plan view, and a first channel region between the first impurity region and the second impurity region and defining a convex portion in a second direction crossing the first direction between the first impurity region and the second impurity region, a second region including a third impurity region, a fourth impurity region spaced apart from the third impurity region by a second length in the first direction in plan view, and a second channel region between the third impurity region and the fourth impurity region and defining a concave portion in a direction opposite to the second direction between the third impurity region and the fourth impurity region, a first gate electrode located on the first channel region of the first region and covering the convex portion and a second gate electrode located on the second channel region of the second region and filling the concave portion, and wherein a third length of the first channel region is longer than the first length, and a fourth length of the second channel region is longer than the second length.

Therefore, as a channel length increases, leakage current, which is one of the short channel effects in the semiconductor device, may be reduced or prevented. In addition, as various grayscale expressions become possible, a color expression of a display device including the semiconductor device may become diverse. Accordingly, a better usage environment may be provided to users who use the display device including the semiconductor device.

However, aspects of the present disclosure are not limited to the above aspects, and may be expanded in various ways without departing from the spirit and scope of the present disclosure.

### BRIEF DESCRIPTION OF THE DRAWINGS

The accompanying drawings, which are included to provide a further understanding of the present disclosure and are incorporated in and constitute a part of this specification, illustrate embodiments of the present disclosure together with the description.

FIG. 1 is a perspective view showing one or more embodiments of a display device of the present disclosure.

FIG. 2 is a diagram showing one or more embodiments of a pixel included in the display device of FIG. 1.

FIG. 3 is a cross-sectional view showing one or more embodiments of a semiconductor device located in the display device of FIG. 1.

FIG. 4 is a cross-sectional view showing one or more other embodiments of a semiconductor device included in the display device of FIG. 1.

FIGS. 5 to 16 are diagrams showing a method of manufacturing the semiconductor device of FIG. 3.

FIG. 17 is a block-diagram showing an electronic device according to an embodiment of the present disclosure.

FIG. 18 is a schematic view of an electronic device according to various embodiments of FIG. 17.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that the present disclosure covers all modifications, equivalents, and replacements within the idea and technical scope of the present disclosure, that each of the features of embodiments of the present disclosure may be combined with each other, in part or in whole, and technically various interlocking and operating are possible, and that each embodiment may be implemented independently of each other, or may be implemented together in an association, unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

In this specification, a plane may be defined by a first direction D1, and by a second direction D2 that crosses the first direction D1. For example, the second direction D2 may be substantially perpendicular to the first direction D1. In addition, a third direction D3 may be a normal direction of the plane. That is, the third direction D3 may be substantially perpendicular to the plane formed by the first direction D1 and by the second direction D2.

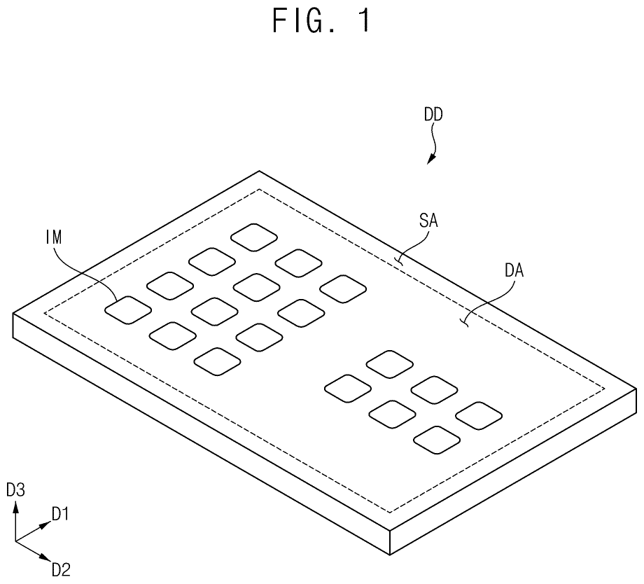

FIG. 1 is a perspective view showing one or more embodiments of a display device of the present disclosure.

Referring to FIG. 1, the display device DD may include a display area DA and a peripheral area SA. The display area DA may be surrounded by the peripheral area SA (e.g., in plan view).

The display area DA may be an area that may display an image by generating light, or by adjusting a transmittance of light provided from an external light source. The peripheral area SA may be an area that does not display an image. However, embodiments of the present disclosure are not necessarily limited thereto, and at least a portion of the peripheral area SA may display an image.

The display area DA may display a plurality of images IM. Users may receive information from the display device DD through the plurality of images IM.

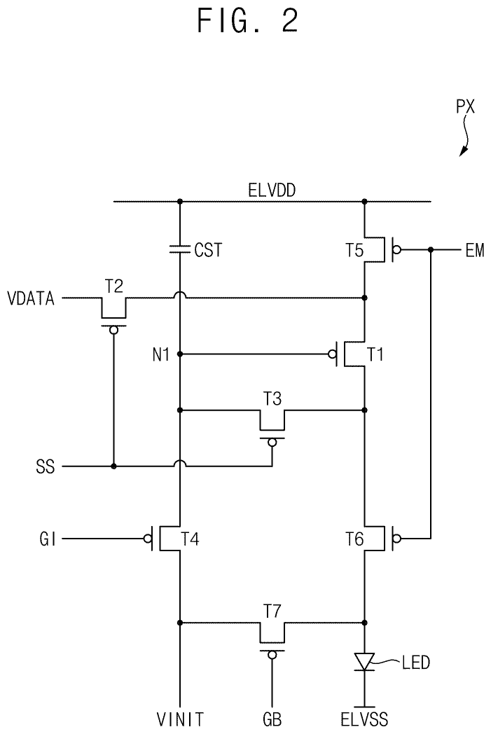

FIG. 2 is a diagram showing one or more embodiments of a pixel included in the display device of FIG. 1.

Referring to FIG. 2, the pixel PX may include first, second, third, fourth, fifth, sixth, and seventh transistors T1, T2, T3, T4, T5, T6, and T7, a capacitor CST, and a light-emitting diode LED.

The first transistor T1 may include a gate electrode, a first electrode, and a second electrode. The gate electrode of the first transistor T1 may be connected to a second electrode of the capacitor CST. The first electrode of the first transistor T1 may be connected to a second electrode of the fifth transistor T5. The second electrode of the first transistor T1 may be connected to a second electrode of the third transistor T3.

The second transistor T2 may include a gate electrode, a first electrode, and a second electrode. A scan signal SS may be applied to the gate electrode of the second transistor T2. A data voltage VDATA may be applied to the first electrode of the second transistor T2. The second electrode of the second transistor T2 may be connected to the first electrode of the first transistor T1.

The third transistor T3 may include a gate electrode, a first electrode, and a second electrode. The scan signal SS may be applied to the gate electrode of the third transistor T3. The first electrode of the third transistor T3 may be connected to a first electrode of the fourth transistor T4. The second electrode of the third transistor T3 may be connected to the second electrode of the first transistor T1.

The fourth transistor T4 may include a gate electrode, the first electrode, and the second electrode. A first initialization signal GI may be applied to the gate electrode of the fourth transistor T4. The first electrode of the fourth transistor T4 may be connected to the first electrode of the third transistor T3. An initialization voltage VINIT may be applied to the second electrode of the fourth transistor T4.

The fifth transistor T5 may include a gate electrode, a first electrode, and a second electrode. An emission control signal EM may be applied to the gate electrode of the fifth transistor T5. A first power voltage ELVDD may be applied to the first electrode of the fifth transistor T5. The second electrode of the fifth transistor T5 may be connected to the first electrode of the first transistor T1.

The sixth transistor T6 may include a gate electrode, a first electrode, and a second electrode. The emission control signal EM may be applied to the gate electrode of the sixth transistor T6. The first electrode of the sixth transistor T6 may be connected to the second electrode of the first transistor T1. The second electrode of the sixth transistor T6 may be connected to a second electrode of the seventh transistor T7.

The seventh transistor T7 may include a gate electrode, a first electrode, and a second electrode. A second initialization signal GB may be applied to the gate electrode of the seventh transistor T7. The initialization voltage VINIT may be applied to the first electrode of the seventh transistor T7. The second electrode of the seventh transistor T7 may be connected to the second electrode of the sixth transistor T6.

The capacitor CST may include a first electrode and a second electrode. The first power voltage ELVDD may be applied to the first electrode of the capacitor CST. The second electrode of the capacitor CST may be connected to the first electrode of the third transistor T3.

The light-emitting diode LED may include a first electrode and a second electrode. The first electrode of the light-emitting diode LED may be connected to the second electrode of the seventh transistor T7. A second common voltage ELVSS may be applied to the second electrode of the light-emitting diode LED.

Meanwhile, in FIG. 2, the pixel PX having a 7T1C structure is shown, but the present disclosure is not necessarily limited thereto. The pixel PX may be configured in various ways, such as 4T2C, 5T2C, 6T2C, 7T2C, and 8T1C.

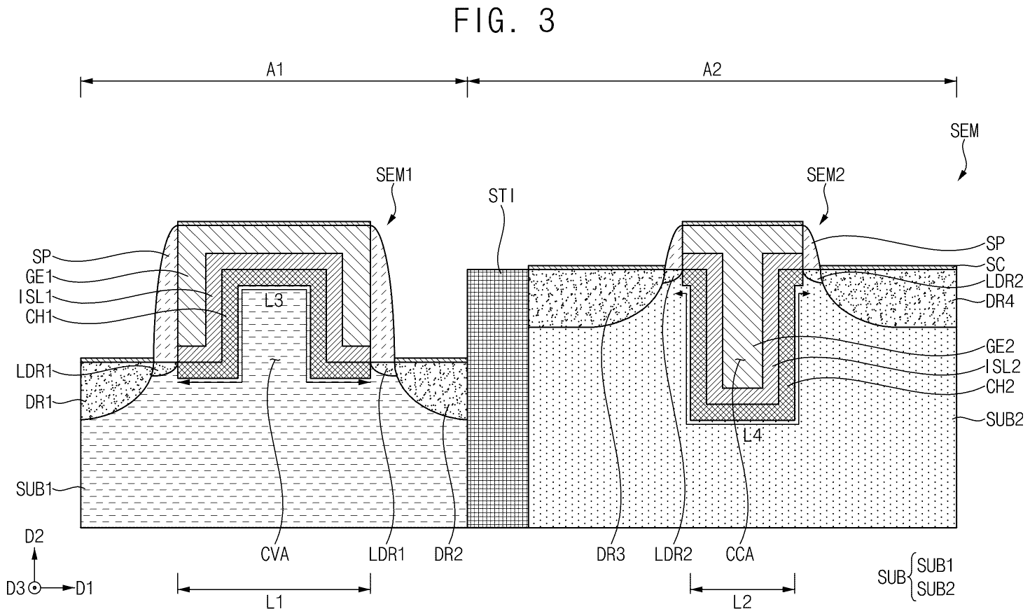

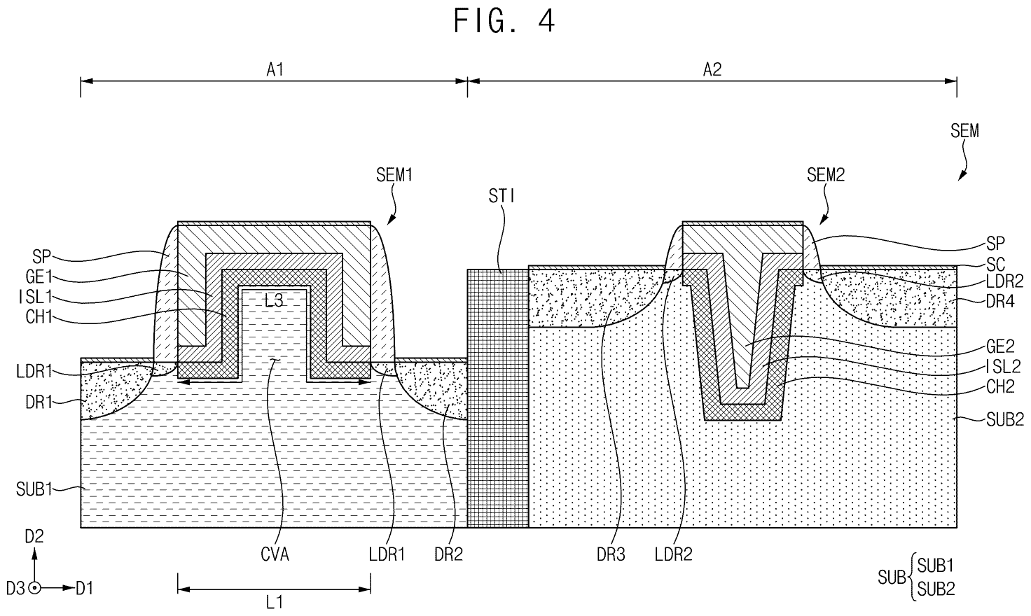

FIG. 3 is a cross-sectional view showing one or more embodiments of a semiconductor device located in the display device of FIG. 1. FIG. 4 is a cross-sectional view showing one or more other embodiments of a semiconductor device included in the display device of FIG. 1.

Referring to FIGS. 3 and 4, the semiconductor device SEM may include a first semiconductor device SEM1 located in a first area A1, and a second semiconductor device SEM2 located in a second area A2 adjacent to the first area A1. The semiconductor device SEM described with reference to FIGS. 3 and 4 may correspond to one of the first, second, third, fourth, fifth, sixth, and seventh transistors T1, T2, T3, T4, T5, T6, and T7 of FIG. 2.

For example, the semiconductor device SEM may include a substrate SUB, first and second insulating layers ISL1 and ISL2, first and second gate electrodes GE1 and GE2, a spacer SP, and a first, second, third, and fourth impurity regions DR1, DR2, DR3, and DR4, first low-concentration impurity regions LDR1, second low-concentration impurity regions LDR2, a device isolation layer STI, and the silicide SC. For example, the substrate SUB may include a first substrate SUB1 located in the first area A1, and a second substrate SUB2 located in the second area A2.

A convex portion CVA that is convex in the second direction D2 may be defined on the first substrate SUB1 located in the first area A1. Conversely, a concave portion CCA that is concave in a direction opposite to the second direction D2 may be defined in the second substrate SUB2 located in the second area A2. However, embodiments of the present disclosure are not necessarily limited thereto. The concave portion CCA may be defined on the first substrate SUB1 in the first area A1, and the convex portion CVA may be defined on the second substrate SUB2 in the second area A2.

The first impurity region DR1, the second impurity region DR2, and the first low-concentration impurity regions LDR1 may be located on the first substrate SUB1.

In one or more embodiments, the first impurity region DR1 and the second impurity region DR2 may be doped with a same material. For example, the first impurity region DR1 and the second impurity region DR2 may be doped with a P-type material. Examples of the P-type material may include boron (B), aluminum (Al), or indium (In) etc. For another example, the first impurity region DR1 and the second impurity region

DR2 may be doped with an N-type material. Examples of the N-type material may include phosphorus (P), arsenic (As), or antimony (Sb) etc. That is, the first semiconductor device SEM1 may be P-MOS or N-MOS.

In one or more embodiments, the third impurity region DR3 and the fourth impurity region DR4 may be doped with a same material. For example, the third impurity region DR3 and the fourth impurity region DR4 may be doped with a P-type material. For another example, the third impurity region DR3 and the fourth impurity region DR4 may be doped with an N-type material. That is, the second semiconductor device SEM2 may be P-MOS or N-MOS.

In one or more embodiments, a level of a top surface of the convex portion CVA may be substantially equal to a level of a top surface of the third impurity region DR3. That is, the convex portion CVA may be formed by etching a portion of the first substrate SUB1, and accordingly, a level of an upper surface of the convex portion CVA may be substantially equal to a level of the upper surface of the third impurity region DR3. However, embodiments of the present disclosure are not necessarily limited thereto.

The first low concentration impurity regions LDR1 may be located between the first impurity region DR1 and the second impurity region DR2. In one or more embodiments, the first low concentration impurity regions LDR1 may be spaced apart by a first length L1 in the first direction D1. The first low concentration impurity regions LDR1 may be doped with a same material as the first impurity region DR1.

The second low concentration impurity regions LDR2 may be located between the third impurity region DR3 and the fourth impurity region DR4. In one or more embodiments, the second low concentration impurity regions LDR2 may be spaced apart by a second length L2 in the first direction D1. The second low concentration impurity regions LDR2 may be doped with a same material as the third impurity region DR3.

The first insulating layer ISL1 may be located on the convex portion CVA of the first substrate SUB1. The first insulating layer ISL1 may include an inorganic insulating material. For example, the first insulating layer ISL1 may include silicon oxide (SiOₓ), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ), etc. These may be used alone or in combination with each other. However, embodiments of the present disclosure are not necessarily limited thereto.

In one or more embodiments, a first channel region CH1 may be formed along a lower portion of the first insulating layer ISL1. That is, the first channel region CH1 may be formed along a top of the convex portion CVA of the first substrate SUB1. The first channel region CH1 may have a third length L3 that is longer than the first length L1. The third length L3 may be about 3 μm or more.

The second insulating layer ISL2 may be located on the concave portion CCA of the second substrate SUB2. The second insulating layer ISL2 may include an inorganic insulating material. For example, the second insulating layer ISL2 may include a same material as the first insulating layer ISL1. These may be used alone or in combination with each other. However, embodiments of the present disclosure are not necessarily limited thereto.

Referring to FIG. 4, in one or more embodiments, the second insulating layer ISL2 may have a V-shape in a cross-sectional view. The second insulating layer ISL2 may have various shapes, such as a U-shape or a V-shape, along the concave portion CCA in a cross-sectional view. That is, the concave portion CCA may have a trench shape in a cross-sectional view. However, embodiments of the present disclosure are not necessarily limited thereto.

In one or more embodiments, a second channel region CH2 may be formed along a lower portion of the second insulating layer ISL2. That is, the second channel region CH2 may be formed along a top of the concave portion CCA. The second channel region CH2 may have a fourth length L4 that is longer than the second length L2. The fourth length L4 may be about 3 μm or more.

As each of the third length L3 of the first channel region CH1 and the fourth length L4 of the second channel region CH2 have a value of about 3 μm or more, a leakage current phenomenon, which is one of the short channel effects in the semiconductor device SEM, may be reduced or prevented. In addition, various gradation expressions are possible, so that the color expression of the display device (e.g., the display device DD in FIG. 1) may be diversified. Accordingly, a better usage environment may be provided to users who use a display device (e.g., display device DD of FIG. 1) including the semiconductor device SEM. As a result, reliability of the display device (e.g., display device DD in FIG. 1) may be improved.

The first gate electrode GE1 may be located on the first insulating layer ISL1. That is, the first gate electrode GE1 may cover the first insulating layer ISL1. The first gate electrode GE1 may include metal, alloy, metal nitride, conductive metal oxide, transparent conductive material, etc. These may be used alone or in combination with each other. However, embodiments of the present disclosure are not necessarily limited thereto.

The second gate electrode GE2 may be located on the second insulating layer ISL2. That is, the second gate electrode GE2 may fill the concave portion CCA. The second gate electrode GE2 may include a same material as the first gate electrode GE1.

The spacer SP may be located on the first low-concentration impurity regions LDR1 and the second low-concentration impurity regions LDR2. The spacer SP may overlap each of the first low-concentration impurity regions LDR1 and the second low-concentration impurity regions LDR2 in plan view. The spacer SP may include an insulating material, such as silicon oxide or silicon nitride. These may be used alone or in combination with each other. However, embodiments of the present disclosure are not necessarily limited thereto.

The silicide SC may be located on the first, second, third, and fourth impurity regions DR1, DR2, DR3, and DR4 and the first and second gate electrodes GE1 and GE2. That is, the silicide SC may overlap with the first, second, third, and fourth impurity regions DR1, DR2, DR3, and DR4 and the first and second gate electrodes GE1 and GE2 in plan view. The silicide SC may lower electrical resistance in the first, second, third, and fourth impurity regions DR1, DR2, DR3, and DR4 and the first and second gate electrodes GE1 and GE2. The silicide SC may include cobalt, nickel, platinum, palladium, vanadium, titanium, tantalum, ytterbium, zirconium, and etc. These may be used alone or in combination with each other. However, embodiments of the present disclosure are not necessarily limited thereto.

The device isolation layer STI may be located between the first area A1 and the second area A2. The device isolation layer STI may distinguish the first semiconductor device SEM1 and the second semiconductor device SEM2. For example, the device isolation layer STI may include an insulating material that fills a device isolation trench formed in the substrate SUB. The device isolation membrane STI may include fluoride silicate glass (FSG), undoped silicate glass (USG), boro-phospho-silicate glass (BPSG), phospho-silicate glass (PSG), flowable oxide (FOX), PE-TEOS (plasma enhanced tetra-ethyl-ortho-silicate), or TOSZ (tonen silazene). These may be used alone or in combination with each other. However, embodiments of the present disclosure are not necessarily limited thereto.

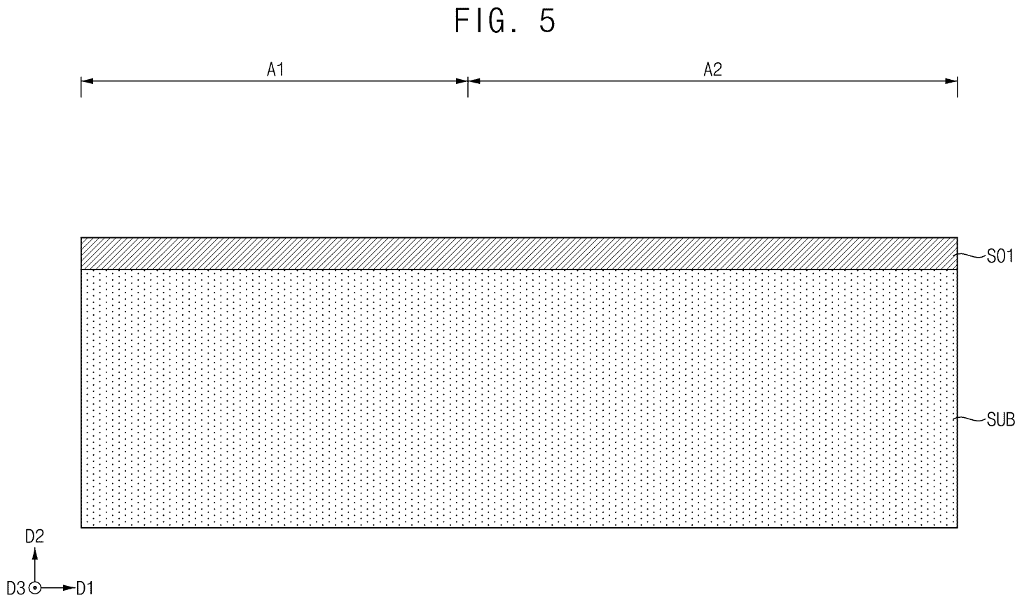

FIGS. 5 to 16 are diagrams showing a method of manufacturing the semiconductor device of FIG. 3.

Referring to FIG. 5, after providing the substrate SUB including the first area A1 and the second area A2, a first oxide layer SO1 may be deposited on the substrate SUB. The substrate SUB may be a substrate doped with a P-type material. The first oxide layer SO1 may include a silicon oxide material. However, embodiments of the present disclosure are not necessarily limited thereto.

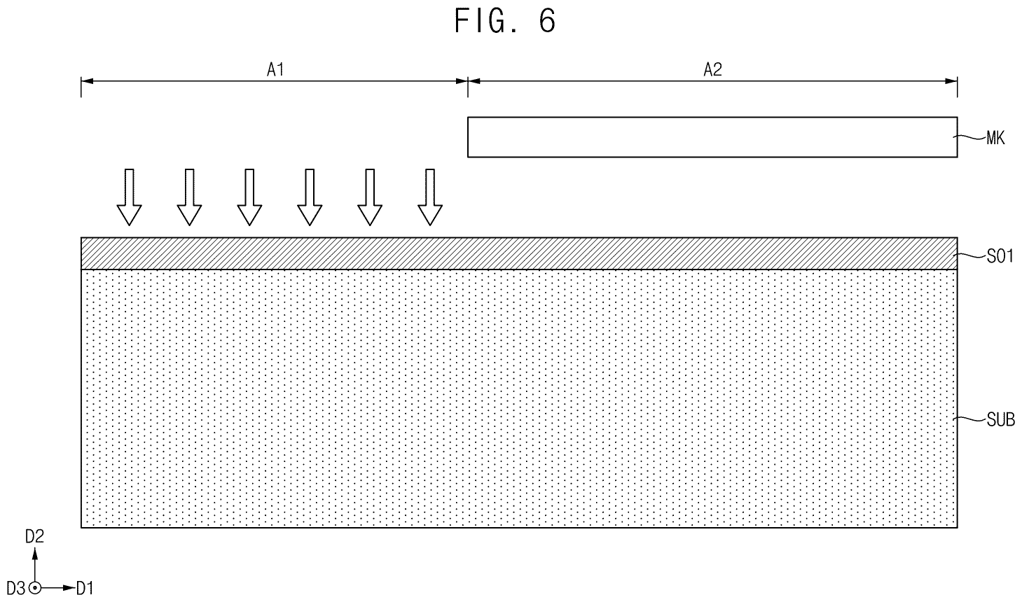

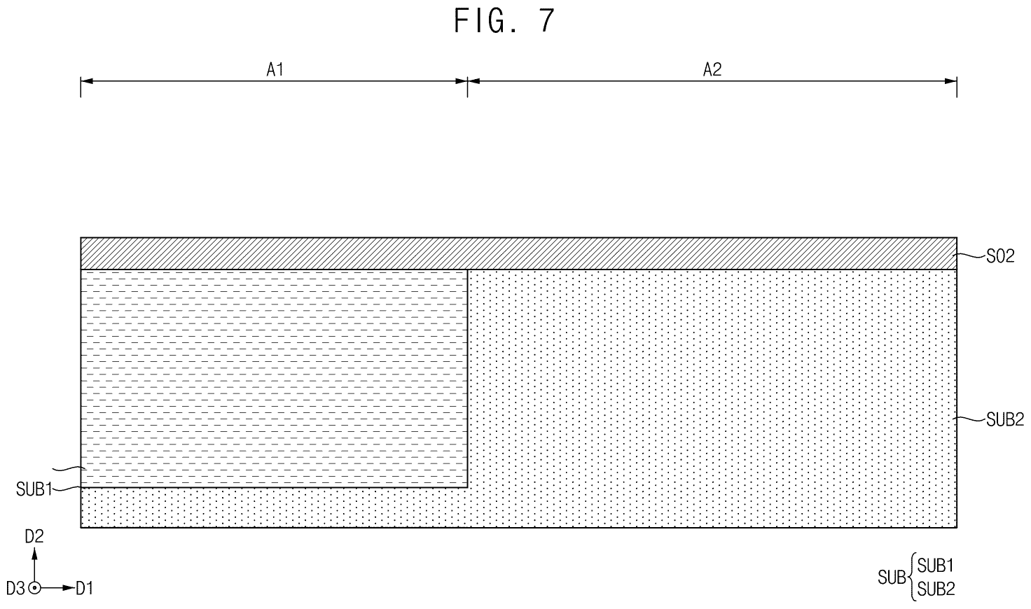

Referring further to FIGS. 6 and 7, a mask MK may be located on the second area A2, and impurities may be doped into at least a portion of the first area A1. Accordingly, the first area A1 may be doped with a material that is different from the second area A2. For example, the first region A1 may be doped with an N-type material. That is, the first area A1 may be the first substrate SUB1 including a N-type material, and the second area A2 may be the second substrate SUB2 including a P-type material. However, embodiments of the present disclosure are not necessarily limited thereto.

After doping the first region A1, the first oxide layer SO1 damaged by doping may be removed. Thereafter, a second oxide layer SO2 may be deposited on the substrate SUB. The second oxide layer SO2 may include a same material as the first oxide layer SO1.

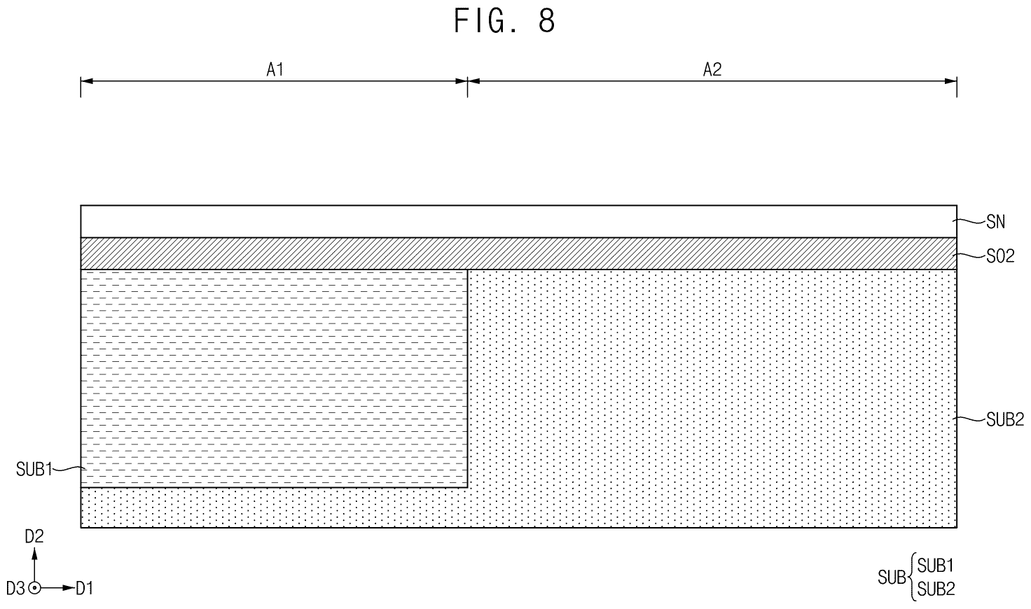

Referring further to FIG. 8, an inorganic insulating layer SN may be deposited on the second oxide layer SO2. The inorganic insulating layer SN may include a silicon nitride material. However, embodiments of the present disclosure are not necessarily limited thereto.

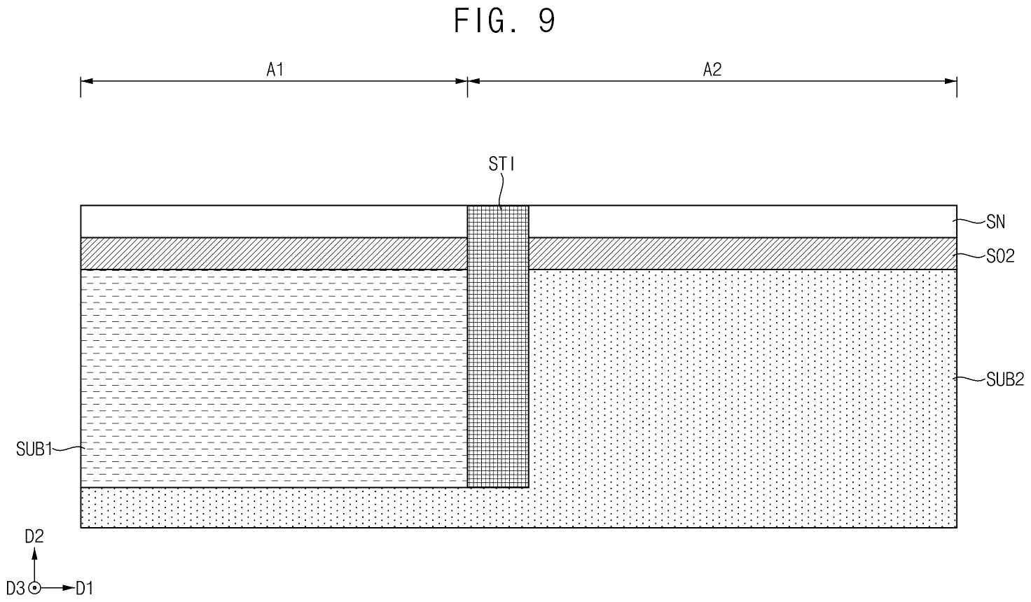

Referring further to FIG. 9, the device isolation layer STI may be formed between the first area A1 and the second area A2. The device isolation layer STI may distinguish the first substrate SUB1 and the second substrate SUB2. The device isolation membrane STI may include fluoride silicate glass (FSG), undoped silicate glass (USG), boro-phospho-silicate glass (BPSG), phospho-silicate glass (PSG), flowable oxide (FOX), PE-TEOS (plasma tetra-ethyl-ortho-silicate), or TOSZ (tonen silazene). These may be used alone or in combination with each other. However, embodiments of the present disclosure are not necessarily limited thereto.

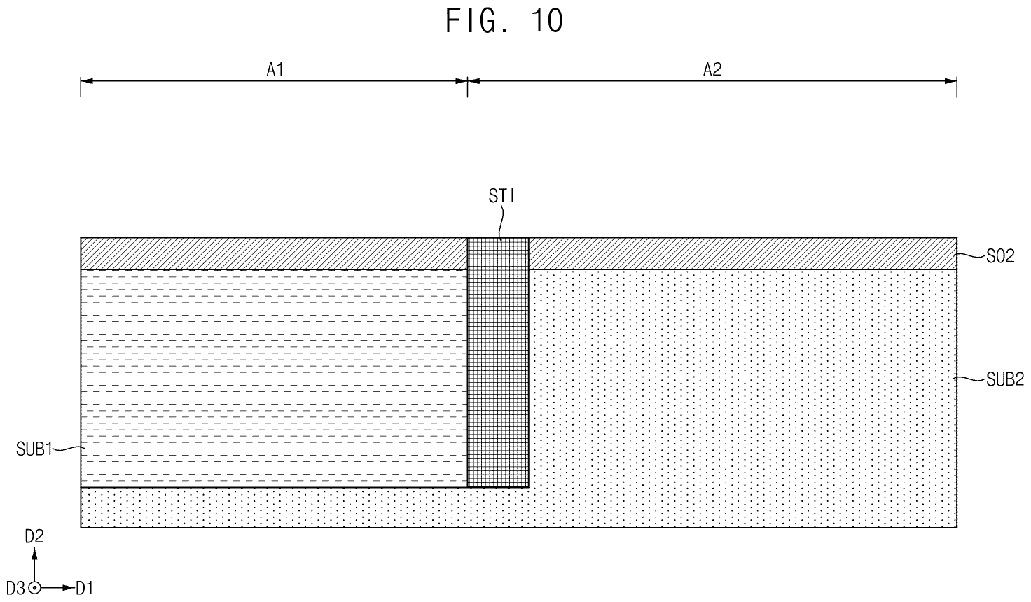

Referring further to FIG. 10, after the device isolation layer STI is formed, the inorganic insulating layer SN may be removed. For example, the inorganic insulating layer SN may be removed through a chemical mechanical polishing (CMP) process.

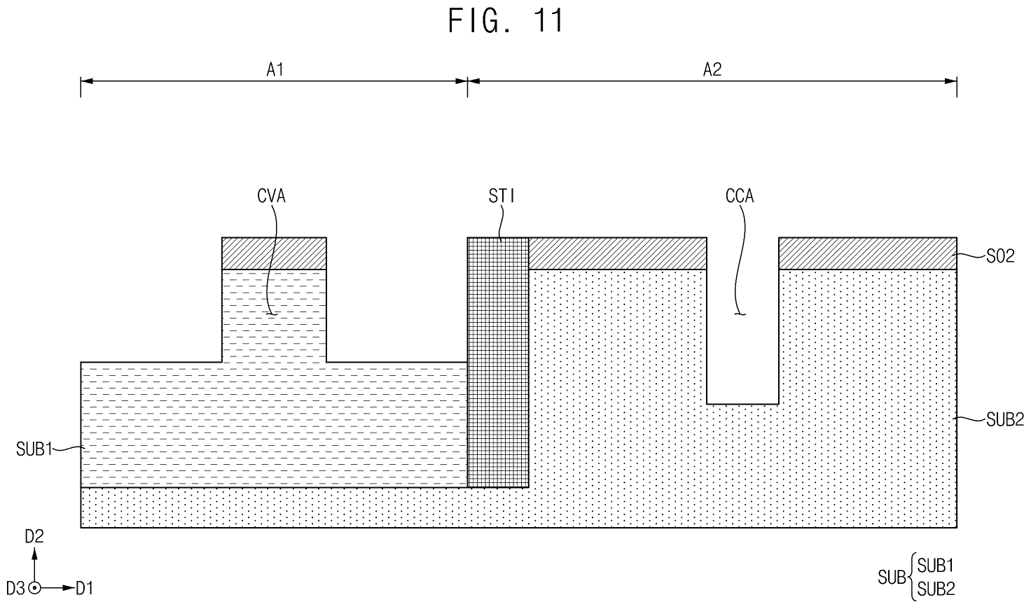

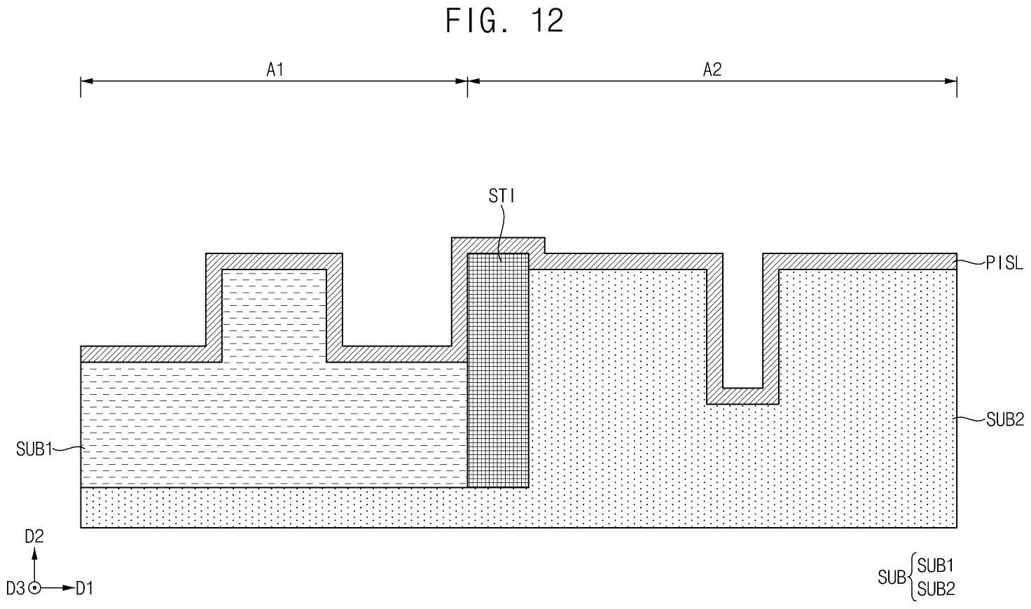

Referring further to FIGS. 11 and 12, a portion of the substrate SUB may be etched to form the convex portion CVA and the concave portion CCA. For example, an area(s) of the first substrate SUB1 in the first area A1 except a central portion may be etched to form the convex portion CVA. A central portion of the second substrate SUB2 in the second area A2 may be etched to form the concave portion CCA. However, embodiments of the present disclosure are not necessarily limited thereto. The concave portion CCA may be formed in the first substrate SUB1, and the convex portion CVA may be formed in the second substrate SUB2.

Accordingly, a level of an upper surface of the convex part CVA may be substantially equal to a level of an upper surface of the second substrate SUB2 other than the concave part CCA. However, embodiments of the present disclosure are not necessarily limited thereto.

Thereafter, after the second oxide layer SO2 is removed, a preliminary insulating layer PISL may be deposited on the substrate SUB. For example, the preliminary insulating layer PISL may be formed to have a constant thickness on the substrate SUB.

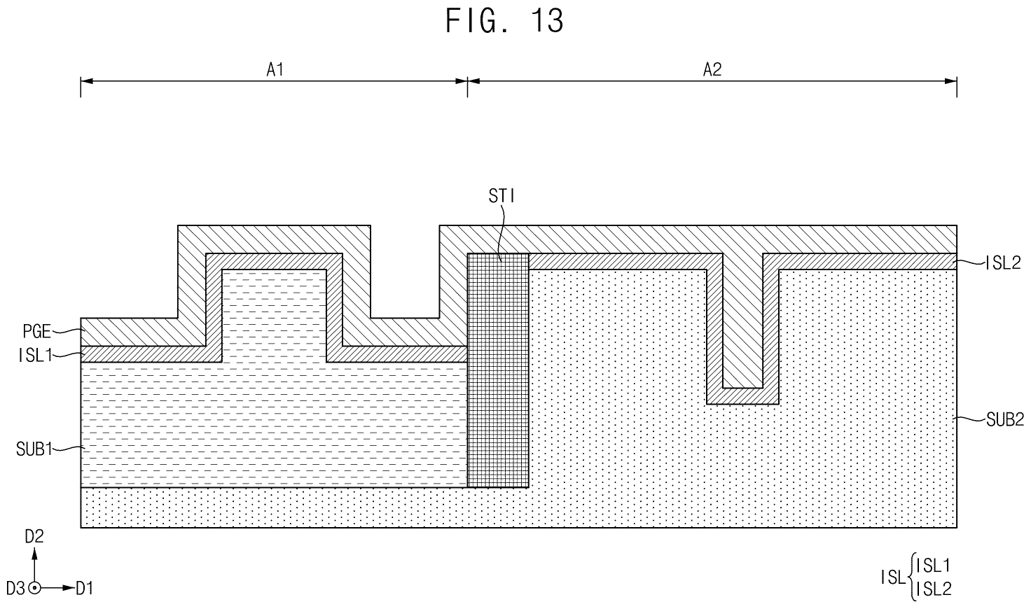

Referring further to FIG. 13, a preliminary gate electrode PGE may be formed on the insulating layer ISL. For example, the preliminary gate electrode PGE may be formed to have a uniform thickness in the first area A1 and the second area A2.

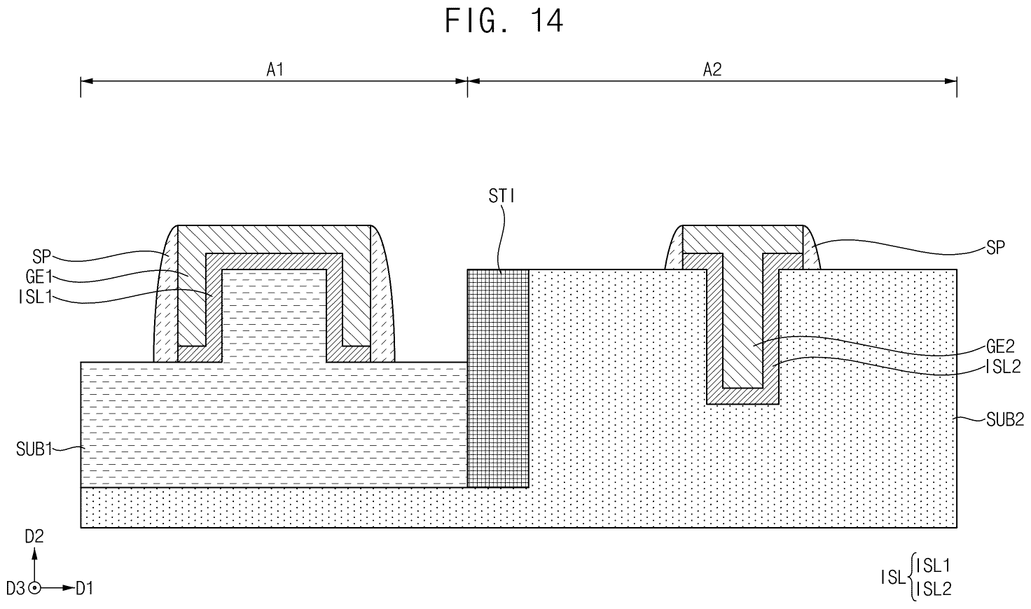

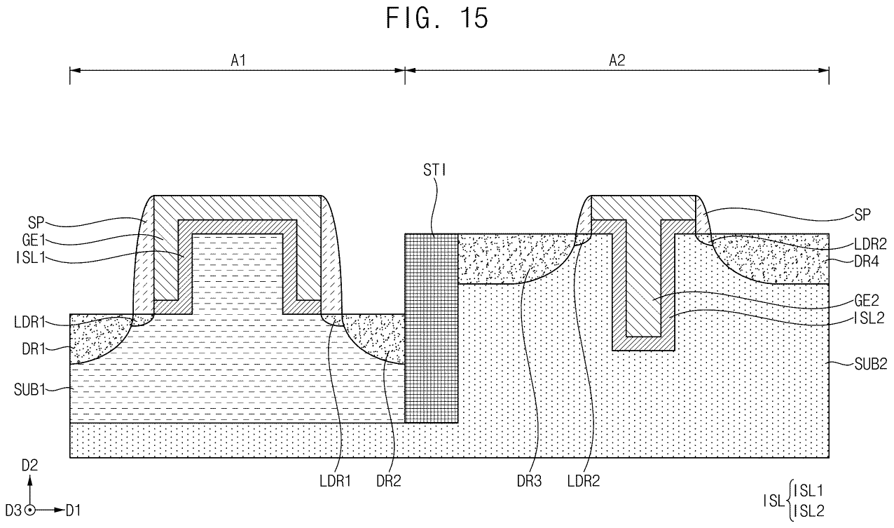

Referring further to FIG. 14, the first gate electrode GE1 and the second gate electrode GE2 may be formed by etching the preliminary gate electrode (e.g., the preliminary gate electrode PGE in FIG. 13). The spacer SP may be formed on a side surface of the first gate electrode GE1, and on a side surface of the second gate electrode GE2. The spacer SP may be used when forming the first low-concentration impurity regions (e.g., the first low-concentration impurity regions LDR1 in FIGS. 15) and the second low-concentration impurity regions (e.g., the second low-concentration impurity regions in FIG. 15).

Referring further to FIG. 15, the first impurity region DR1, the second impurity region DR2, and the first low-concentration impurity regions LDR1 may be formed on an upper surface of the first substrate SUB1 in the first area A1. The third impurity region DR3, the fourth impurity region DR4, and the second low-concentration impurity regions LDR2 may be formed on an upper surface of the second substrate SUB2 in the second area A2.

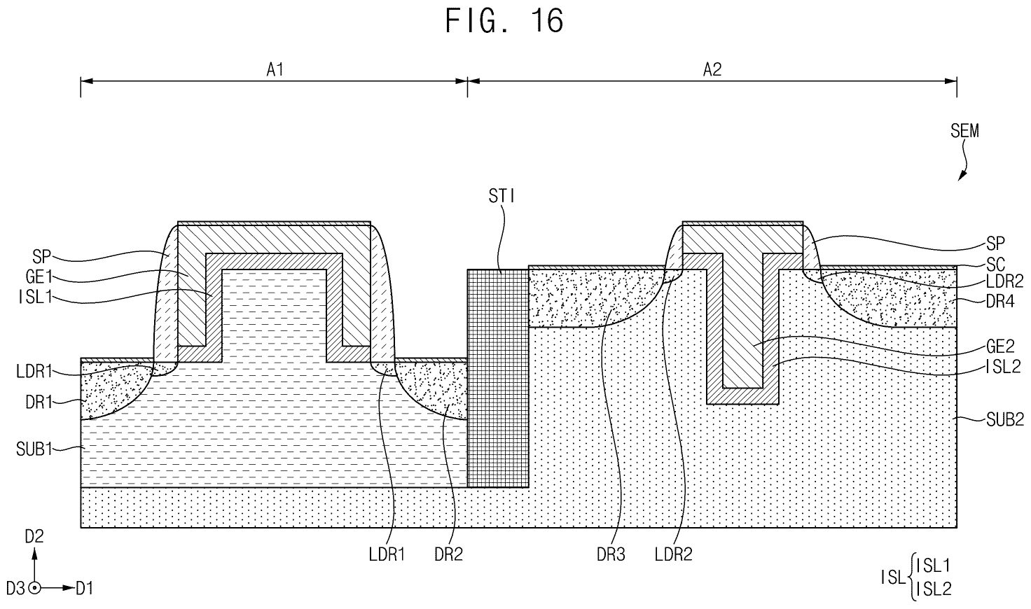

Referring further to FIG. 16, the silicide SC may be formed on the first, second, third, and fourth impurity regions DR1, DR2, DR3, and DR4 and on the first and second gate electrodes GE1 and GE2. The silicide SC may lower electrical resistance in the first, second, third, and fourth impurity regions DR1, DR2, DR3, and DR4 and in the first and second gate electrodes GE1 and GE2.

As a result, as the convex portion CVA and the concave portion CCA may be formed, so that a length of the channel region of the semiconductor device SEM may be increased. Accordingly, a leakage current phenomenon in the semiconductor device SEM may be reduced or prevented, so the reliability of the display device (e.g., the display device DD of FIG. 1) may be improved.

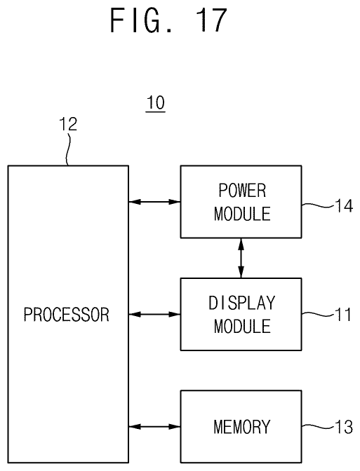

FIG. 17 is a block-diagram showing an electronic device according to an embodiment of the present disclosure.

Referring to FIG. 1 and FIG. 17, the display device DD according to the embodiments may be applied to various electronic devices 10. The electronic device 10 according to an embodiment may include the display device DD, and may further include a module or device including additional functions in addition to the display device DD.

The electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information necessary for an operation of the processor 12 or the display module 11. When the processor 12 executes an application stored in the memory 13, an image data signal and/or an input control signal may be transmitted to the display module 11, and the display module 11 may process the received signal and output image information through a display screen.

The power module 14 may include a power supply module such as a power adapter or a battery device, and a power conversion module that converts the power supplied by the power supply module to generate power necessary for an operation of the electronic device 10.

At least one of the components of the electronic device 10 described above may be included in the display device according to the embodiments described above. In addition, some of individual modules functionally included in one module may be included in the display device, and other parts may be provided separately from the display device. For example, the display device DD may include the display module 11, and the processor 12, the memory 13, and the power module 14 may be provided in the form of other devices within the electronic device 10 other than the display device DD.

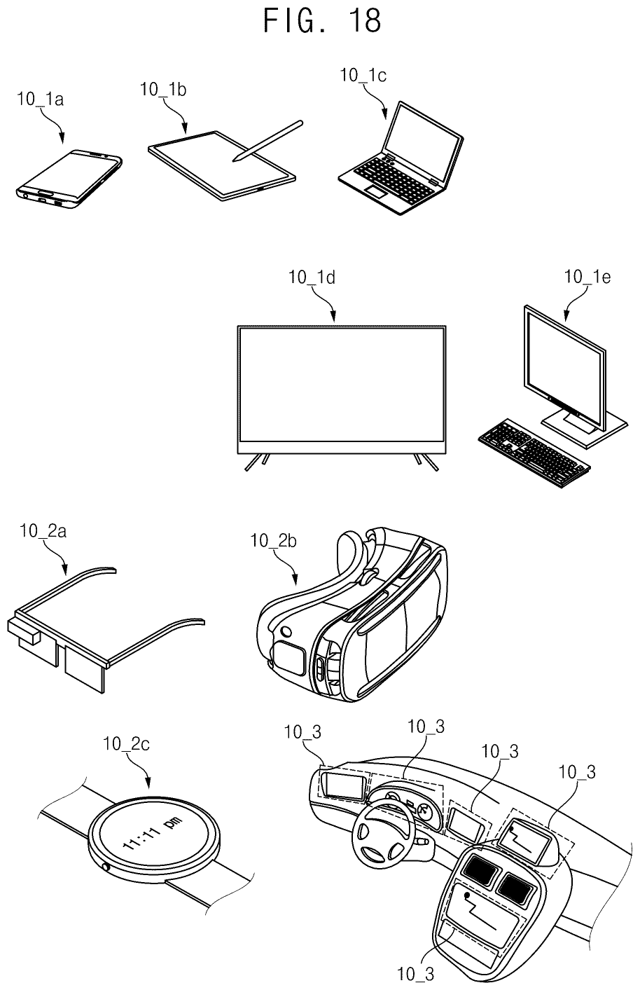

FIG. 18 is a schematic view of an electronic device according to various embodiments of FIG. 17.

Referring to FIG. 17 and FIG. 18, various electronic devices to which the display device DD according to embodiments is applied may include not only image display electronic devices such as a smart phone 10_1a, a tablet PC 10_1b, a laptop 10_1c, a TV 10_1d, and a desk monitor 10_1e, but also wearable electronic devices including display modules such as smart glasses 10_2a, a head-mounted display 10_2b, and a smart watch 10_2c, and vehicle electronic devices 10_3 including display modules such as a CID (center information display) and a room mirror display placed on a dashboard, center fascia, or dashboard of an automobile.

However, this is exemplary, and the electronic device 10 according to embodiments of the present disclosure is not limited thereto. For example, the electronic device 10 may be implemented as a mobile phone, a video phone, a smart pad, a smart watch, a tablet PC, a vehicle display, a computer monitor, a notebook computer, a head-mounted display device, etc. In addition, the electronic device 10 may be a television, a monitor, a notebook computer, or a tablet. In addition, the electronic device 10 may be an automobile.

The present disclosure may be applied to the display device and the electronic device including a same. For example, the present disclosure may be applied to high-resolution smartphones, mobile phones, smart pads, smart watches, tablet PCs, vehicle navigation systems, televisions, computer monitors, laptops, etc.

While the disclosure has been particularly shown and described with reference to embodiments thereof, it will be understood by those of ordinary skill in the art that various changes in form and details may be made therein without departing from the spirit or scope of the disclosure as defined by the following claims, with functional equivalents thereof to be included therein.

what is claimed is:

1. A semiconductor device comprising:
a substrate comprising:
a first region comprising:
a first impurity region;
a second impurity region spaced apart from the first impurity region by a first length in a first direction in a plan view; and
a first channel region having a third length that is longer than the first length between the first impurity region and the second impurity region, the first region defining a convex portion that is convex in a second direction crossing the first direction between the first impurity region and the second impurity region,
a second region comprising:
a third impurity region;
a fourth impurity region spaced apart from the third impurity region by a second length in the first direction in a plan view; and
a second channel region having a fourth length that is longer than the second length between the third impurity region and the fourth impurity region, the second region defining a concave portion that is concave in a direction opposite to the second direction between the third impurity region and the fourth impurity region;
a first gate electrode above the first channel region, and covering the convex portion; and
a second gate electrode above the second channel region, and filling the concave portion.

2. The semiconductor device of claim 1, further comprising a device isolation layer between the first region and the second region.

3. The semiconductor device of claim 1, wherein the third length and the fourth length is about 3 μm or more.

4. The semiconductor device of claim 1, wherein the concave portion is U-shaped or V-shaped in a cross-sectional view.

5. The semiconductor device of claim 1, wherein the first impurity region and the second impurity region are doped with a P-type material, and
wherein the third impurity region and the fourth impurity region are doped with an N-type material.

6. The semiconductor device of claim 1, wherein the first, second, third, and fourth impurity regions are doped with a P-type material.

7. The semiconductor device of claim 1, wherein the first, second, third, and fourth impurity regions are doped with an N-type material.

8. The semiconductor device of claim 1, further comprising:
a first insulating layer between the substrate and the first gate electrode in the first region; and
a second insulating layer between the substrate and the second gate electrode in the second region.

9. The semiconductor device of claim 8, wherein the first insulating layer overlaps the first gate electrode in plan view, and
wherein the second insulating layer overlaps the second gate electrode in plan view.

10. The semiconductor device of claim 8, wherein the first channel region is at a lower portion of the first insulating layer, and
wherein the second channel region is at a lower portion of the second insulating layer.

11. The semiconductor device of claim 1, wherein a level of an upper surface of the convex portion is substantially equal to a level of an upper surface of the third impurity region.

12. The semiconductor device of claim 1, further comprising:
first low-concentration impurity regions between the first impurity region and the first channel region, and between the second impurity region and the first channel region; and
second low-concentration impurity regions between the third impurity region and the second channel region, and between the fourth impurity region and the second channel region.

13. The semiconductor device of claim 12, wherein the first low-concentration impurity regions are doped with a same material as the first impurity region, and
wherein the second low-concentration impurity regions are doped with a same material as the third impurity region.

14. The semiconductor device of claim 1, further comprising a silicide above the first, second, third, and fourth impurity regions, the first gate electrode, and the second gate electrode.

15. A method of manufacturing a semiconductor device comprising:
providing a substrate comprising a first region, and a second region adjacent to the first region in a first direction;
forming a device isolation layer between the first region and the second region;
forming a convex portion that is convex in a second direction crossing the first direction in a central portion of the first region and a concave portion that is concave in a direction opposite to the second direction in a central portion of the second region by etching the substrate;
forming a first gate electrode that covers the convex portion of the first region; and
forming a second gate electrode that fills the concave portion of the second region.

16. The method of claim 15, further comprising, after forming the concave portion and the convex portion, forming a first insulating layer between the substrate and the first gate electrode in the first region, and a second insulating layer between the substrate and the second gate electrode in the second region.

17. The method of claim 16, wherein a length of a first channel region beneath the first insulating layer, and a length of a second channel region beneath the second insulating layer, is about 3 μm or more.

18. The method of claim 15, further comprising, after providing the substrate, doping at least a portion of the first region with an impurity.

19. The method of claim 18, wherein the impurity is an N-type material.

20. The method of claim 15, wherein the substrate is doped with a P-type material.

21. An electronic device comprising:
a display device; and
a processor that drives the display device, and
wherein the display device includes
a substrate comprising:
a first region comprising:
a first impurity region;
a second impurity region spaced apart from the first impurity region by a first length in a first direction in a plan view; and
a first channel region having a third length that is longer than the first length between the first impurity region and the second impurity region, the first region defining a convex portion that is convex in a second direction crossing the first direction between the first impurity region and the second impurity region,
a second region comprising:
a third impurity region;
a fourth impurity region spaced apart from the third impurity region by a second length in the first direction in a plan view; and
a second channel region having a fourth length that is longer than the second length between the third impurity region and the fourth impurity region, the second region defining a concave portion that is concave in a direction opposite to the second direction between the third impurity region and the fourth impurity region;
a first gate electrode above the first channel region, and covering the convex portion; and
a second gate electrode above the second channel region, and filling the concave portion.
